(19) United States
(12) Patent Application Publication
(10) Pub. No.: US 2011/0017289 A1
(43) Pub. Date: Jan. 27, 2011

(54) CIGS SOLAR CELL AND METHOD OF FABRICATING THE SAME

(75) Inventors: Rae-Man PARK, Daejeon (KR); Chull Won Ju, Daejeon (KR); Dae-Hyung Cho, Seoul (KR); Yong-Duck Chung, Daejeon (KR); Sung-Bum Bae, Daejeon (KR); Won Seok Han, Daejeon (KR); Kyu-Seok Lee, Seo-gu (KR); Je Ha Kim, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/769,756

(22) Filed: Apr. 29, 2010

(30) Foreign Application Priority Data
Jul. 24, 2009 (KR) 10-2009-0067824
Dec. 16, 2009 (KR) 10-2009-0125467

(51) Int. Cl. H01L 31/032; H01L 31/18

(52) U.S. Cl. 136/256; 438/95; 257/E31.027

(57) ABSTRACT

Provided are a CIGS solar cell and a method of fabricating the CIGS solar cell. In the method, a buffer layer exposing protrusions is formed. Then, a window electrode layer having an uneven surface conforming with the protrusions of the buffer layer is formed. Thus, an additional process for making the upper surface of a window electrode layer rough is unnecessary in order to decrease surface reflectance of incident sunlight and increase the solar cell efficiency, so that productivity can be improved.

### CROSS-REFERENCE TO RELATED APPLICATIONS

This U.S. non-provisional patent application claims priority under 35 U.S.C. §119 of Korean Patent Application Nos. 10-2009-0067824, filed on Jul. 24, 2009, and 10-2009-0125467, filed on Dec. 16, 2009, the entire contents of which are hereby incorporated by reference.

### BACKGROUND OF THE INVENTION

The present invention disclosed herein relates to a solar cell and a method of fabricating the solar cell, and more particularly, to a copper-indium-gallium-selenide (CIGS) solar cell capable of decreasing surface reflectance of incident sunlight, and a method of fabricating the CIGS solar cell.

Thin film solar cells may be classified into amorphous or crystalline silicon thin layer solar cells, CIGS solar cells, CdTe thin layer solar cells, and dye sensitized solar cells, according to materials. Comparing to amorphous silicon solar cells, CIGS solar cells have high efficiency and no initial performance degradation. Thus, CIGS solar cells are the subject of much interest. Such a CIGS solar cell has an energy conversion efficiency of about 19.9% in a single junction structure.

To increase the energy conversion efficiency of CIGS solar cells, technologies such as a multi layered structure or an upper sunlight reflection-preventing layer have been developed. For example, when a CIGS solar cell further includes a sunlight reflection-preventing layer containing MgF, the absolute value of energy conversion efficiency is increased by about 1 to 2%. In addition, a surface of the outermost layer of a CIGS solar cell may be made rough to increase energy conversion efficiency.

### SUMMARY OF THE INVENTION

The present invention provides a CIGS solar cell, which is easily fabricated and has improved efficiency, and a method of fabricating the CIGS solar cell.

The present invention also provides a CIGS solar cell capable of improving productivity without an additional fabricating process for increasing energy conversion efficiency, and a method of fabricating the CIGS solar cell.

Embodiments of the present invention provide methods of fabricating a copper-indium-gallium-selenide solar cell, the methods including: forming a lower electrode layer on a substrate; forming a light absorption layer on the lower electrode layer; forming a buffer layer including a plurality of exposed protrusions, on the light absorption layer; and forming a window electrode layer having an uneven upper surface conforming with the protrusions of the buffer layer.

In some embodiments, the buffer layer may be formed using a chemical bath deposition method in which a basic solution is used as a solvent.

In other embodiments, the basic solution may include an aqueous ammonia having a concentration ranging from about 2% to about 5%.

In still other embodiments, the chemical bath deposition method may use a reaction solution dissolved in the basic solution to form the buffer layer of cadmium sulfide.

In even other embodiments, the reaction solution may include a mixed solution of thiourea and cadmium sulfate.

In yet other embodiments, the chemical bath deposition method may be used at a temperature ranging from about 50° C. to about 80° C.

In other embodiments of the present invention, a copper-indium-gallium-selenide solar cell include: a lower electrode layer disposed on a substrate; a light absorption layer disposed on the lower electrode layer; a buffer layer including a plurality of exposed protrusions and disposed on the light absorption layer; and an uneven window electrode layer conforming with the protrusions of the buffer layer and disposed on the buffer layer.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a cross-sectional view illustrating a copper-indium-gallium-selenide (CIGS) thin film solar cell according to an embodiment of the present invention;

FIG. 2 is a graph illustrating the light reflectance of an buffer layer of FIG. 1;

FIG. 3 is a graph illustrating improved energy conversion efficiency of the CIGS solar cell of FIG. 1;

FIGS. 4A through 4E are cross-sectional views illustrating a method of fabricating a CIGS thin solar cell according to an embodiment of the present invention;

FIG. 5 is an image illustrating a surface of a buffer layer formed using a method of fabricating a CIGS thin film solar cell according to an embodiment of the present invention; and

FIG. 6 is a graph illustrating heights of a buffer layer, which is measured in alpha step.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the figures, the dimensions of elements are exaggerated for clarity of illustration. Like reference numerals refer to like elements throughout. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

Hereinafter, it will be described about exemplary embodiments of the present invention in conjunction with the accompanying drawings.

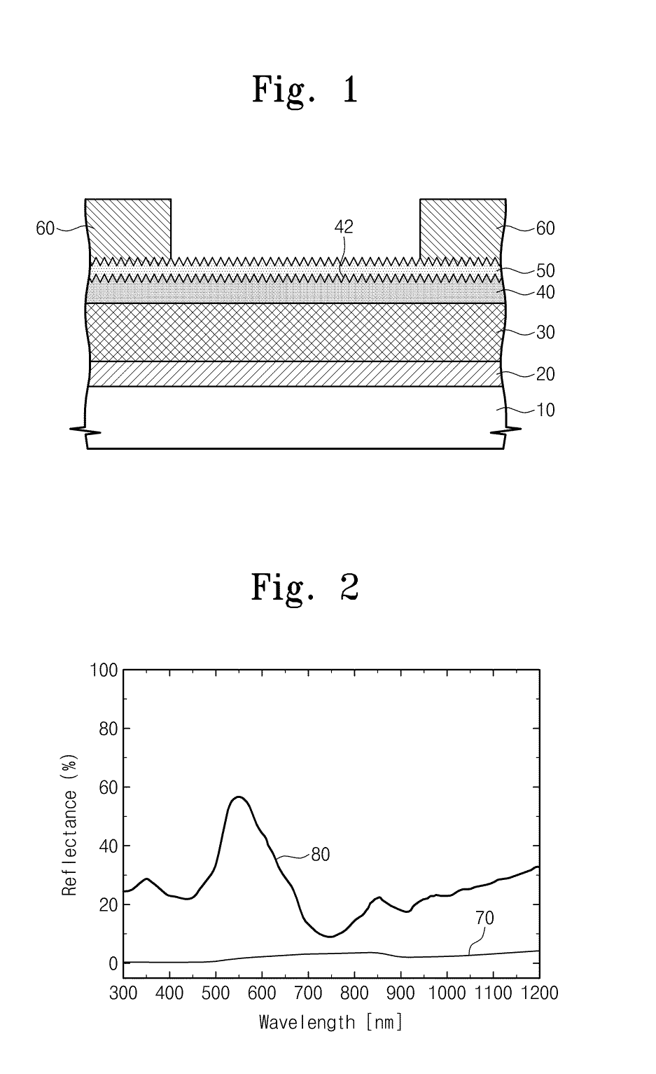

FIG. 1 is a cross-sectional view illustrating a copper-indium-gallium-selenide (CIGS) solar cell according to an embodiment of the present invention.

Referring to FIG. 1, the CIGS solar cell may include a window electrode layer 50 having a rough surface. A buffer layer 40 may be disposed under the window electrode layer 50. The buffer layer 40 may include a plurality of protrusions 42 such that the window electrode layer 50 has the rough surface. Thus, the rough surface of the window electrode layer 50 may conform with the protrusions 42 provided to the buffer layer 40.

The window electrode layer 50 maximally transmits sunlight without reflecting sunlight. The buffer layer 40 also maximally transmits sunlight transmitted by the window electrode layer 50. The buffer layer 40 and the window electrode layer 50 minimize reflectance of sunlight. An upper electrode layer 60 may be disposed on the window electrode layer 50. A flat lower electrode layer 20 and a light absorption layer 30 are disposed between a substrate 10 and the buffer layer 40.

The substrate 10 may be a sodalime glass substrate that is inexpensive. Sodium of the sodalime glass substrate is spread into the light absorption layer 30 to improve photovoltaic characteristics of the CIGS solar cell. Alternatively, the substrate 10 may be a substrate formed of ceramic such as alumina, a metal substrate including a stainless steel plate or a copper tape, or a high polymer film.

The lower electrode layer 20 may have low specific resistance and high adhesion to a glass substrate to prevent exfoliation due to discrepancies in thermal expansion coefficient. In detail, the lower electrode layer 20 may be formed of molybdenum. Molybdenum may have high electrical conductivity, ohmic contact formation characteristics with a thin layer, and high temperature stability under selenium (Se) atmosphere.

The light absorption layer 30 may generate electrons and holes by using light energy transmitted by the buffer layer 40 and the window electrode layer 50. The light absorption layer 30 may include a chalcopyrite based compound semiconductor containing any one selected from the group consisting of CuInSe, CuInSe₂, CuInGaSe, and CuInGaSe₂. The chalcopyrite based compound semiconductor may have an energy band gap of about 1.2 eV.

The buffer layer 40 may buffer the energy band gaps of the window electrode layer 50 and the light absorption layer 30. The energy band gap of the buffer layer 40 may be greater than that of the light absorption layer 30, and less than that of the window electrode layer 50. For example, the buffer layer 40 may include cadmium sulfide (CdS) that may have a constant energy band gap of about 2.4 eV.

The buffer layer 40 may prevent damage of the light absorption layer 30 when the window electrode layer 50 is formed. The buffer layer 40 may improve bonding degradation due to lattice constant discrepancy between the light absorption layer 30 and the window electrode layer 50. For example, the buffer layer 40 may have a hexagonal crystal structure.

FIG. 2 is a graph illustrating a light reflectance of the buffer layer 40 of FIG. 1. In the CIGS solar cell according to the current embodiment, the buffer layer 40 having the protrusions 42 has a reflectance 70 that is significantly lower than a reflectance 80 of a related art flat buffer layer. The light reflectance 70 of the buffer layer 40 including the protrusions 42 ranges from about 3% to about 5% according to the wavelength band of incident light. The light reflectance 80 of the related art flat buffer layer ranges from about 10% to about 50% according to the wavelength band of incident light. The wavelength of the incident light ranges from about 300 nm to about 1200 nm.

Thus, the reflectance of the CIGS solar cell according to the current embodiment can be decreased using the buffer layer 40 including the protrusions 42 under the window electrode layer 50.

The window electrode layer 50 may be formed of a material having high light transmissivity and high electrical conductivity. For example, the window electrode layer 50 may be formed of zinc oxide (ZnO). ZnO may have a band gap of about 3.2 eV. ZnO may be doped with aluminum or boron to decrease its resistance value. Alternatively, the window electrode layer 50 may further include an indium tin oxide (ITO) thin layer that has excellent electrooptical characteristics. The light transmissivity of the window electrode layer 50 may be varied according to the light reflectance of the upper surface exposed to air. The upper electrode layer 60 may be disposed on the window electrode layer 50. The upper electrode layer 60 may be a grid electrode that collects a current from the window electrode layer 50. The upper electrode layer 60 may define at least one cell exposing the window electrode layer 50. The upper electrode layer 60 may include at least one of aluminum and nickel. A portion taken by the upper electrode layer 60 should be minimized since it does not receive sunlight.

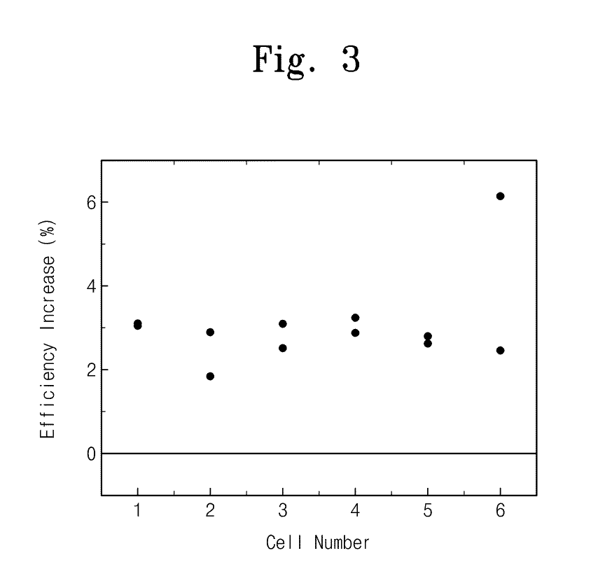

FIG. 3 is a graph illustrating improved energy conversion efficiency of the CIGS solar cell of FIG. 1. Referring to FIG. 3, the energy conversion efficiency of the CIGS solar cell of FIG. 1 is greater than that (0%) of a related art solar cell by about 2% through about 6%. The horizontal axis of the graph represents a plurality of cell numbers, and the vertical axis represents the energy conversion efficiency increase of the CIGS solar cell of FIG. 1, relative to the related art energy conversion efficiency. When the related art energy conversion efficiency is about 12%, the energy conversion efficiency of the CIGS solar cell of FIG. 1 may range from about 14% to about 18%.

Thus, the CIGS solar cell according to the current embodiment includes the buffer layer 40 having the rough surface and the window electrode layer 50 having the rough surface to improve the energy conversion efficiency.

A method of fabricating a CIGS solar cell configured as described above will now be described according to an embodiment of the present invention.

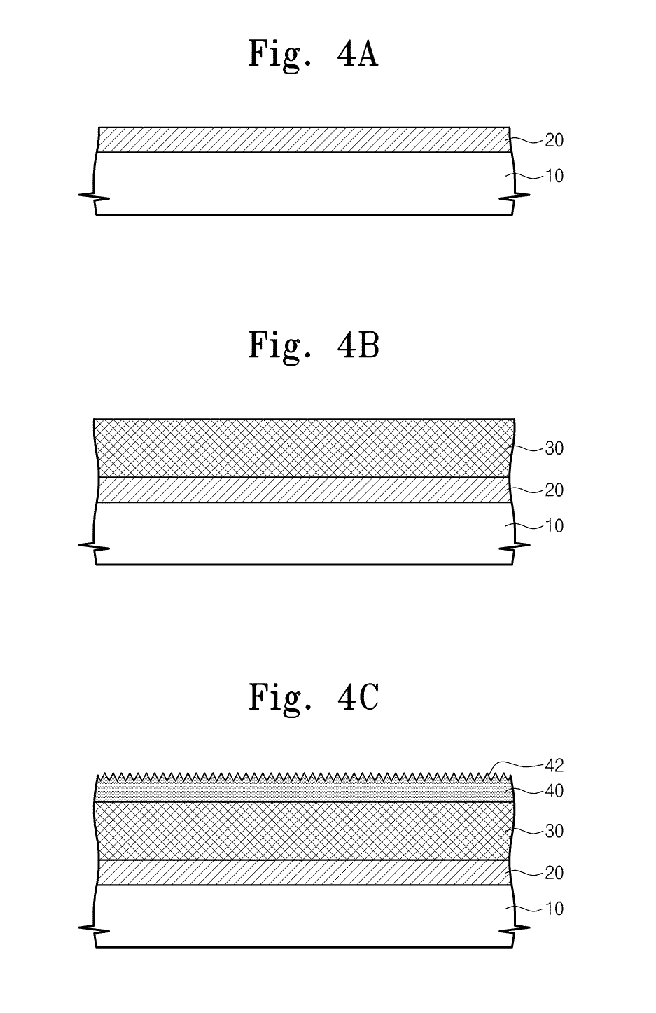

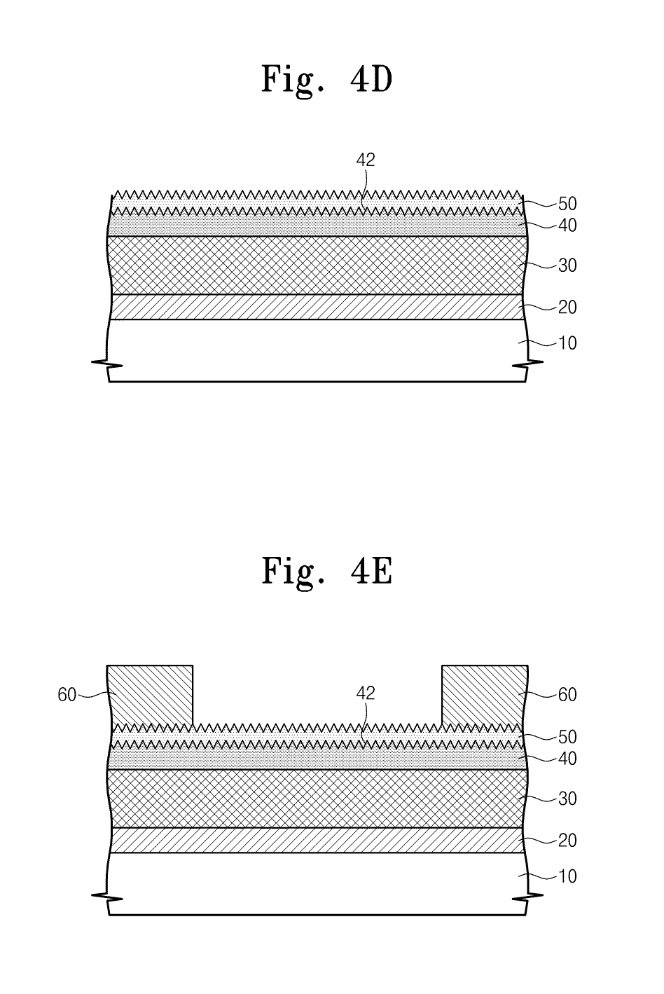

FIGS. 4A through 4E are cross-sectional views illustrating a method of fabricating a CIGS solar cell according to an embodiment of the present invention.

Referring to FIG. 4A, the lower electrode layer 20 is formed on the substrate 10. The substrate 10 may be one of a soda lime glass substrate, a substrate formed of ceramic such as alumina, a metal substrate including a stainless steel plate or a copper tape, and a high polymer film. In the current embodiment, the substrate 10 may be a soda lime glass substrate. The lower electrode layer 20 may be formed using a sputtering method or an electron beam deposition method. The lower electrode layer 20 may be formed of a material that has low specific resistance and high adhesion to a glass substrate to prevent exfoliation due to discrepancies in thermal expansion coefficient. In detail, the lower electrode layer 20 may be formed of molybdenum. Molybdenum may have high electrical conductivity, ohmic contact formation characteristics with a thin layer, and high temperature stability under selenium (Se) atmosphere. The lower electrode layer 20 may have a thickness ranging from about 0.5 nm to about 1 nm.

Referring to FIG. 4B, the light absorption layer 30 is formed on the lower electrode layer 20. The light absorption layer 30 may include a chalcopyrite based compound semiconductor containing any one selected from the group consisting of CuInSe, CuInSe₂, CuInGaSe, and CuInGaSe₂. The chalcopyrite based compound semiconductor may be referred to as a CIGS based thin layer.

The light absorption layer 30 may be formed using a co-evaporation method. The light absorption layer 30 may be formed by simultaneously evaporating indium (In), copper (Cu), selenium (Se), gallium (Ga), and nitrogen (N). In detail, the CIGS based thin layer may be deposited using an indium effusion cell, a copper effusion cell, a selenium effusion cell, a gallium effusion cell, and a nitrogen cracker. For example, the indium effusion cell may be In₂Se₃, the copper effusion cell may be Cu₂Se, the gallium effusion cell may be Ga₂Se₃, and the selenium effusion cell may be Se. The effusion cells may be high-purity materials, e.g., of 99.99% or greater purity. When the light absorption layer 30 is formed, the substrate 10 may have a temperature ranging from about 300° C. to about 600° C. The light absorption layer 30 may have a thickness ranging from about 1 μm to about 3 μm. The light absorption layer 30 may be a single layer or a multi-layered structure.

Referring to FIG. 4C, the buffer layer 40 is formed on the light absorption layer 30. The buffer layer 40 may include cadmium sulfide that may be formed using a chemical bath deposition (CBD) method. In the CBD method, a basic solution may be used as a solvent. The basic solution may include an aqueous ammonia (NH₃+H₂O) having a concentration ranging from about 2% to about 5%. The aqueous ammonia may have pH ranging from about 7 to 9.

In the CBD method, a mixed solution of thiourea (NH₂CSNH₂) and cadmium sulfate 3(CdSO₄)*8(H₂O) may be used as a reaction solution or a solute. The thiourea and the cadmium sulfate may be mixed in a concentration ratio ranging from about 1:1 through about 1:5. The solvent and the solute may be reacted as Chemical Formula (1).

CdSO₄+4NH₃+NH₂CSNH₂+8H₂O→[Cd(NH₃)₄]²⁺+(SO₄)²⁻+NH₂CSNH₂+8H₂O (1)

In this case, the cadmium sulfate (CdSO₄) may be converted into the cadmium ammonia ion [Cd(NH₃)₄]²⁺. The sulfate ion (SO₄)²⁻ may be left in the solvent and the solute without being used in a chemical conversion that will be performed later. Thereafter, the cadmium sulfide may be formed on the light absorption layer 30 through extraction as Chemical Formula (2).

[Cd(NH₃)₄]²⁺+NH₂CSNH₂+2OH⁻→CdS+4NH₃+CH₂N₂+2H₂O (2)

In this case, the cadmium ammonia ion [Cd(NH₃)₄]²⁺ may be reacted with the thiourea (NH₂CSNH₂) to extract the cadmium sulfide (CdS), and to generate the ammonia (4NH₃) and diazomethane (CH₂N₂). The ammonia (4NH₃) and the water (H₂O) may be converted into the aqueous ammonia. The ammonia (4NH₃) may be used to control the extraction amount of the cadmium sulfide (CdS). That is, as the concentration of the aqueous ammonia is decreased, the cadmium sulfide is rapidly grown.

Thus, in the method of fabricating the CIGS solar cell according to the current embodiment, the extraction rate of the cadmium sulfide on the light absorption layer 30 is increased to form the buffer layer 40 including the protrusions 42.

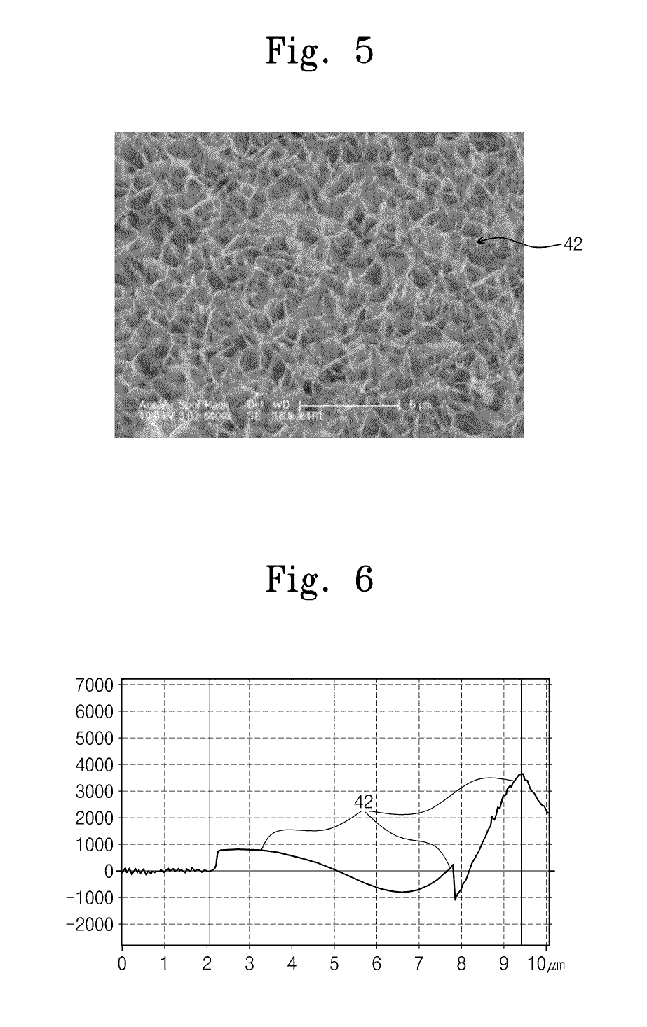

The aqueous ammonia may be heated to a temperature ranging from about 50° C. to about 80° C. during the reaction to accelerate the extraction rate of the cadmium sulfide. Under this condition, the buffer layer 40 from which the protrusions 42 are exposed may be formed on the light absorption layer 30 as illustrated in FIG. 5.

FIG. 6 is a graph illustrating the heights of protrusions formed on a buffer layer, which is measured in alpha step. The buffer layer 40 may include the protrusions 42 having uneven heights within a given range. The horizontal axis may represent distances between the protrusions 42 in μm, and the vertical axis may represent heights of the protrusions 42 in Å. An arbitrary position of the buffer layer 40 may be set as a reference point. The protrusions 42 of the buffer layer 40 may be uneven in height and width. For example, the number of the protrusions 42 disposed within a distance of about 8 μm may be three. The protrusions 42 may have similar heights from the reference point, or have the maximum height of about 3600 Å from the reference point.

Thus, the buffer layer 40 including the protrusions 42 having uneven widths and uneven heights may be formed using the method of fabricating the CIGS solar cell according to the current embodiment.

Referring to FIG. 4D, the window electrode layer 50 is formed on the buffer layer 40. The window electrode layer 50 may be formed of a material having high light transmissivity and high electrical conductivity. The window electrode layer 50 may be formed of zinc oxide (ZnO). ZnO may have a band gap of about 3.2 eV, and have a high light transmissivity of about 90% or greater. ZnO may be doped with aluminum or boron to decrease its resistance value. Alternatively, the window electrode layer 50 may further include an indium tin oxide (ITO) thin layer that has excellent electrooptical characteristics.

The window electrode layer 50 may be formed using a sputtering method or a chemical vapor deposition method. The window electrode layer 50 may have an uneven surface conforming with the protrusions 42 provided to the buffer layer 40. The window electrode layer 50 may have a thickness ranging from about 200 nm to about 3000 nm.

Referring to FIG. 4E, the upper electrode layer 60 is formed on the window electrode layer 50. The upper electrode layer 60 may include at least one of aluminum and nickel. The upper electrode layer 60 may be patterned to have the minimum area and the minimum line width so as to increase sunlight incident efficiency. The upper electrode layer 60 may be patterned through a photolithography process. The upper electrode layer 60 may be in ohmic contact with the window electrode layer 50. The upper electrode layer 60 may collect a current generated from the light absorption layer 30.

According to the embodiment of the present invention, the buffer layer exposing the protrusions is formed on the light absorption layer. Then, the window electrode layer having an uneven surface conforming with the protrusions is formed on the buffer layer. Thus, sunlight reflected from the surface of the window electrode layer is minimized, so that energy conversion efficiency can be increased or maximized.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of fabricating a copper-indium-gallium-selenide solar cell, the method comprising:
forming a lower electrode layer on a substrate;
forming a light absorption layer on the lower electrode layer;
forming a buffer layer including a plurality of exposed protrusions, on the light absorption layer; and
forming a window electrode layer having an uneven upper surface conforming with the protrusions of the buffer layer.

2. The method of claim 1, wherein the buffer layer is formed using a chemical bath deposition method in which a basic solution is used as a solvent.

3. The method of claim 2, wherein the basic solution comprises an aqueous ammonia having a concentration ranging from about 2% to about 5%.

4. The method of claim 3, wherein the chemical bath deposition method uses a reaction solution dissolved in the basic solution to form the buffer layer of cadmium sulfide.

5. The method of claim 4, wherein the reaction solution comprises a mixed solution of thiourea and cadmium sulfate.

6. The method of claim 2, wherein the chemical bath deposition method is used at a temperature ranging from about 50° C. to about 80° C.

7. A copper-indium-gallium-selenide solar cell comprising:
a lower electrode layer disposed on a substrate;
a light absorption layer disposed on the lower electrode layer;
a buffer layer including a plurality of exposed protrusions and disposed on the light absorption layer; and
an uneven window electrode layer conforming with the protrusions of the buffer layer and disposed on the buffer layer.
